(19) United States
(12) Patent Application Publication
(10) Pub. No.: US 2025/0081626 A1
(43) Pub. Date: Mar. 6, 2025

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: MASATO NOBORIO, Nisshin-shi (JP); JUN SAITO, Nisshin-shi (JP)

(21) Appl. No.: 18/753,221

(22) Filed: Jun. 25, 2024

(30) Foreign Application Priority Data
Sep. 1, 2023 (JP) 2023-142299

(51) Int. Cl. H01L 27/02

(52) U.S. Cl. CPC H10D 89/814

(57) ABSTRACT

A semiconductor device includes a semiconductor substrate having at least one element region in which a transistor is disposed, an interlayer insulating film disposed above the semiconductor substrate, and a semiconductor layer disposed above the interlayer insulating film. The semiconductor layer includes a first semiconductor layer of a first conductivity type connected to a gate of the transistor, a second semiconductor layer of a second conductivity type connected to the first semiconductor layer, and a third semiconductor layer of the first conductivity type connected to the second semiconductor layer and connected to a low potential terminal of the transistor.

### CROSS REFERENCE TO RELATED APPLICATION

The present application claims the benefit of priority from Japanese Patent Application No. 2023-142299 filed on Sep. 1, 2023. The entire disclosure of the above application is incorporated herein by reference.

### TECHNICAL FIELD

The present disclosure relates to a semiconductor device.

### BACKGROUND

There has been known a semiconductor device including a main transistor and a protection transistor.

### SUMMARY

The present disclosure provides a semiconductor device including a semiconductor substrate having at least one element region in which a transistor is disposed, an interlayer insulating film disposed above the semiconductor substrate, and a semiconductor layer disposed above the interlayer insulating film. The semiconductor layer includes a first semiconductor layer of a first conductivity type connected to a gate of the transistor, a second semiconductor layer of a second conductivity type connected to the first semiconductor layer, and a third semiconductor layer of the first conductivity type connected to the second semiconductor layer and connected to a low potential terminal of the transistor.

### BRIEF DESCRIPTION OF DRAWINGS

Objects, features and advantages of the present disclosure will become apparent from the following detailed description made with reference to the accompanying drawings. In the drawings:

FIG. 1 is a top view of a semiconductor device according to a first embodiment;

FIG. 2 is a cross-sectional view of a part of the semiconductor device taken along line II-II in FIG. 1;

FIG. 3 is an equivalent circuit diagram of the semiconductor device according to the first embodiment;

FIG. 4 is a cross-sectional view of a part of a semiconductor device according to a second embodiment;

FIG. 5 is an equivalent circuit diagram of the semiconductor device according to the second embodiment;

FIG. 6 is a cross-sectional view of a part of a semiconductor device according to a third embodiment;

FIG. 7 is a cross-sectional view of a part of a semiconductor device according to a fourth embodiment;

FIG. 8 is a top view of a semiconductor layer of a semiconductor device according to a modification; and

FIG. 9 is a top view of a semiconductor layer of a semiconductor device according to another modification.

### DETAILED DESCRIPTION

Next, a relevant technology is described only for understanding the following embodiments. A semiconductor device according to the relevant technology includes a main transistor and a protection transistor. The protection transistor is connected between a gate and a source of the main transistor, and a gate of the protection transistor is connected to the gate of the main transistor.

In the semiconductor device described above, a threshold voltage of the protection transistor is set to be higher than a threshold voltage of the main transistor. Therefore, during normal operation, the protection transistor does not turn on and the operation of the main transistor is not impaired. On the other hand, when an overcurrent flows through the main transistor and the temperature of the main transistor rises, the temperature of the protection transistor also rises, and therefore the threshold voltage of the protection transistor is decreased. Accordingly, the protection transistor is turned on, the gate and the source of the main transistor are short-circuited, and the main transistor is forcibly turned off. As a result, the main transistor can be protected from thermal breakdown.

In the semiconductor device described above, the main transistor and the protection transistor are formed adjacent to each other inside one semiconductor substrate. Therefore, when the main transistor operates, the protection transistor may operate parasitically and the operation of the main transistor may be impaired.

A semiconductor device according to an aspect of the present disclosure includes a semiconductor substrate having at least one element region in which a transistor is disposed, an interlayer insulating film disposed above the semiconductor substrate, and a semiconductor layer disposed above the interlayer insulating film. The semiconductor layer includes a first semiconductor layer of a first conductivity type connected to a gate of the transistor, a second semiconductor layer of a second conductivity type connected to the first semiconductor layer, and a third semiconductor layer of the first conductivity type connected to the second semiconductor layer and connected to a low potential terminal of the transistor.

In the semiconductor device according to the above aspect, the semiconductor layer is connected between the gate and the low potential terminal in the order of the first semiconductor layer of the first conductivity type, the second semiconductor layer of the second conductivity type, and the third semiconductor layer of the first conductivity type. Therefore, during normal operation of the semiconductor device, no current flows through the semiconductor layer and the operation of the transistor is not impaired. On the other hand, when an overcurrent flows through the transistor and the temperature of the semiconductor substrate rises, the heat transfers to the semiconductor layer through the interlayer insulating film, and the temperature of the semiconductor layer also rises. As a result, electron-hole pairs are generated inside the second semiconductor layer, and the resistance of the second semiconductor layer decreases. As a result, a current flows from the gate of the transistor through the semiconductor layer to the low potential terminal of the transistor, and the gate and the low potential terminal of the transistor are short-circuited. As a result, the transistor is forcibly turned off. In the semiconductor device, the transistor and the semiconductor layer are physically separated by the interlayer insulating film. Thus, during normal operation of the transistor, parasitic conduction of the semiconductor layer can be restricted. Therefore, the semiconductor device according to the above aspect can effectively protect the transistor from thermal destruction while restricting impairment of the operation of the transistor.

In the semiconductor device according to the above aspect, the semiconductor substrate may further include a peripheral region disposed around the at least one element region when the semiconductor substrate is viewed from above, and the semiconductor layer may be disposed in the peripheral region.

In such a configuration, since the semiconductor layer is disposed in the peripheral region where no main current flows, a large area for the element region can be secured.

In the semiconductor device according to the above aspect, the at least one element region may include two element regions, and the semiconductor layer may be disposed in a range sandwiched between the two element regions when the semiconductor substrate is viewed from above.

When an overcurrent flows through the transistor, the element region generates heat. In such a configuration, since the semiconductor layer is disposed in the range sandwiched between the element regions that generate heat, the temperature of the semiconductor layer is easily increased, and a short circuit can be quickly formed between the gate and the low potential terminal of the transistor.

In the semiconductor device according to the above aspect, a material that constitutes the semiconductor layer may have a smaller band gap than a material that constitutes the semiconductor substrate.

In such a configuration, the semiconductor layer becomes conductive before a high potential terminal and the low potential terminal of the transistor are short-circuited, so that the gate and the low potential terminal of the transistor can be short-circuited.

In the semiconductor device according to the above aspect, a peak concentration of a first conductivity type impurity in each of the first semiconductor layer and the third semiconductor layer may be 1×10¹⁸ cm⁻³ or more, and a peak concentration of a second conductivity type impurity in the second semiconductor layer may be 5×10¹⁷ cm⁻³ or less.

In such a configuration, a contact resistance between the first and third semiconductor layers and each terminal can be reduced. Furthermore, the second semiconductor layer can quickly reduce a resistance when the temperature of the second semiconductor layer increases.

In the semiconductor device according to the above aspect, the first conductivity type may be n-type, the second conductivity type may be p-type, and a region in the first semiconductor layer being in contact with the second semiconductor layer may have a lower n-type impurity concentration than a region in the first semiconductor layer being in contact with the gate.

In such a configuration, since there is a region with a relatively low concentration of n-type impurity in the first semiconductor layer of n-type located close to the gate, a higher voltage can be maintained between the gate and the low potential terminal when a positive voltage is applied to the gate.

In the semiconductor device according to the above aspect, the first conductivity type may be p-type, the second conductivity type may be n-type, and a region in the third semiconductor layer being in contact with the second semiconductor layer may have a lower p-type impurity concentration than a region in the third semiconductor layer being in contact with the low potential terminal.

In such a configuration, since there is a region with a relatively low concentration of p-type impurity in the third semiconductor layer of p-type located close to the low potential terminal, a higher voltage can be maintained between the gate and the low potential terminal when a positive voltage is applied to the gate.

In the semiconductor device according to the above aspect, the semiconductor substrate may be made of a wide-gap semiconductor, and the semiconductor layer may be made of polysilicon.

### First Embodiment

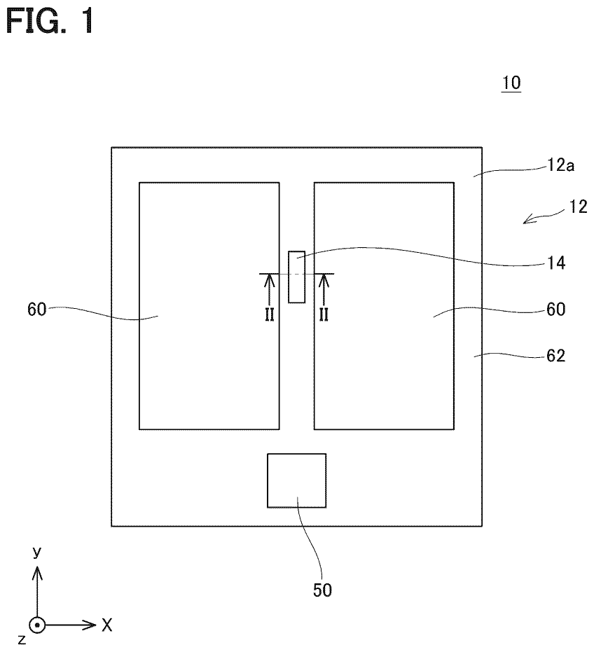

A semiconductor device 10 according to a first embodiment of the present disclosure will be described with reference to the drawings. The semiconductor device 10 shown in FIG. 1 includes a semiconductor substrate 12, electrodes, an insulating layer, and the like. In the following, a direction parallel to an upper surface 12a of the semiconductor substrate 12 may also be referred to as an x-direction, a direction parallel to the upper surface 12a and perpendicular to the x-direction may also be referred to as a y-direction, and a thickness direction of the semiconductor substrate 12 may also be referred to as a z-direction. As shown in FIG. 1, the semiconductor substrate 12 has two element regions 60 and a peripheral region 62. In each of the element regions 60, a transistor 20 (see FIG. 3) is disposed. The two element regions 60 are arranged with an interval therebetween in the x-direction. The transistor 20 in the present embodiment is an n-type metal-oxide-semiconductor field-effect transistor (MOSFET). The peripheral region 62 is disposed around each of the element regions 60. The peripheral region 62 is a region between each of the element regions 60 and an outer peripheral edge of the semiconductor substrate 12, and a region between the two element regions 60. In FIG. 1, the electrodes, the insulating film and the like on the upper surface 12a of the semiconductor substrate 12 are not shown for the ease of viewing. The semiconductor substrate 12 is made of SiC. However, the semiconductor substrate 12 is not limited to SiC, and may be made of other wide-gap semiconductors such as GaN, Ga₂O₃, diamond, or a semiconductor such as silicon Si. In the peripheral region 62, a gate pad 50 is disposed on the upper surface 12a of the semiconductor substrate 12.

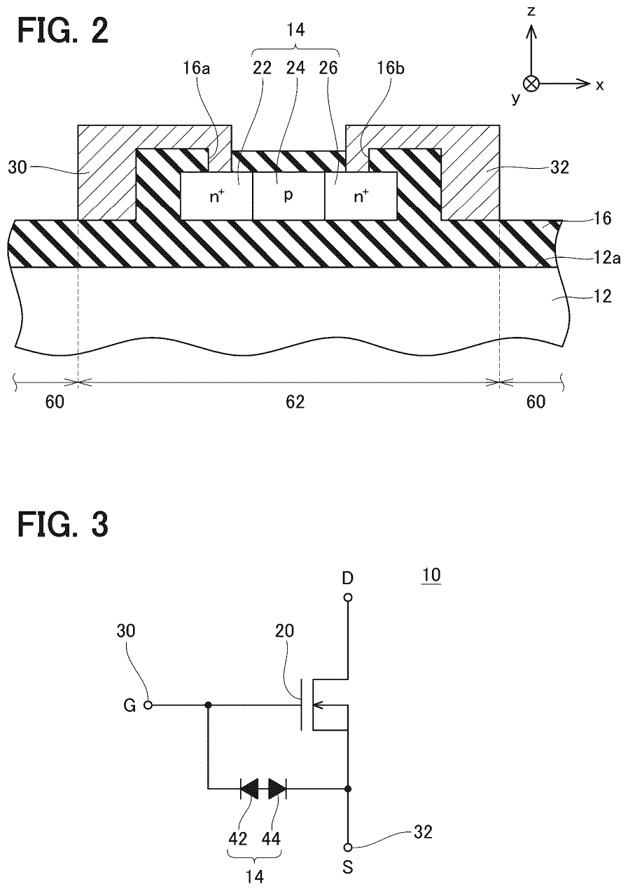

FIG. 2 is a cross-sectional view of a part of the semiconductor device 10 taken along line II-II in FIG. 1. In detail, FIG. 2 shows a cross section of a portion of the semiconductor substrate 12 close to the upper surface 12a. As shown in FIG. 2, an interlayer insulating film 16 is disposed above the upper surface 12a of the semiconductor substrate 12. Although not shown, an n-type MOSFET structure is formed inside the semiconductor substrate 12 in each of the element regions 60. The n-type MOSFET may be of a trench type or a planar type. The interlayer insulating film 16 covers most of the upper surface 12a of the semiconductor substrate 12 across the element regions 60 and the peripheral region 62.

A semiconductor layer 14 is disposed above the interlayer insulating film 16. The semiconductor layer 14 is physically separated from the semiconductor substrate 12 by the interlayer insulating film 16. The interlayer insulating film 16 is also in contact with a side surface and an upper surface of the semiconductor layer 14. That is, the semiconductor layer 14 is covered with the interlayer insulating film 16. As shown in FIG. 1, the semiconductor layer 14 is disposed in a range sandwiched between the two element regions 60 within the peripheral region 62 when the semiconductor substrate 12 is viewed from above.

The semiconductor layer 14 is made of a material having a band gap smaller than a band gap of a material that constitutes the semiconductor substrate 12. Specifically, the semiconductor layer 14 is made of polysilicon. As shown in FIG. 2, the semiconductor layer 14 includes a first semiconductor layer 22, a second semiconductor layer 24, and a third semiconductor layer 26.

The first semiconductor layer 22 is of n-type. The first semiconductor layer 22 is connected to a gate electrode 30 via a contact hole 16a provided in the interlayer insulating film 16. The gate electrode 30 functions as a gate electrode of a transistor (that is, the n-type MOSFET) disposed in each of the element regions 60. The gate electrode 30 faces a body region (more specifically, a body region between a source region and a drain region) disposed inside the semiconductor substrate 12 via a gate insulating film at a position not shown. A peak concentration of an n-type impurity in the first semiconductor layer 22 is 1×10¹⁸ cm⁻³ or more.

The second semiconductor layer 24 is of p-type. The second semiconductor layer 24 is connected to the first semiconductor layer 22. A peak concentration of a p-type impurity in the second semiconductor layer 24 is 5×10¹⁷ cm 3 or less.

The third semiconductor layer 26 is of n-type. The third semiconductor layer 26 is connected to the second semiconductor layer 24. The second semiconductor layer 24 is disposed between the third semiconductor layer 26 and the first semiconductor layer 22, and the third semiconductor layer 26 is separated from the first semiconductor layer 22 by the second semiconductor layer 24. In addition, the third semiconductor layer 26 is connected to a source electrode 32 via a contact hole 16b provided in the interlayer insulating film 16. The source electrode 32 functions as a source electrode of the transistor (that is, the n-type MOSFET) disposed in each of the element regions 60. The source electrode 32 is in ohmic contact with the source region disposed inside the semiconductor substrate 12 at a position not shown. A peak concentration of an n-type impurity in the third semiconductor layer 26 is 1×10¹⁸ cm⁻³ or more.

As shown in FIGS. 1 and 2, the first semiconductor layer 22, the second semiconductor layer 24, and the third semiconductor layer 26 each extend along the y-direction.

FIG. 3 shows an equivalent circuit diagram of the semiconductor device 10. As described above, the semiconductor device 10 of the first embodiment includes the semiconductor layer 14 in which the first semiconductor layer 22, the second semiconductor layer 24, and the third semiconductor layer 26 are connected in this order between the gate electrode 30 and the source electrode 32. In other words, as shown in FIG. 3, in the semiconductor device 10, a diode 42 that is in a reverse direction from a gate G to a source S of the transistor 20 and a diode 44 that is in a forward direction from the gate G to the source S of the transistor 20 are connected in series in this order between the gate G and the source S. In other words, in the semiconductor layer 14, a cathode of the diode 42 is connected to the gate G of the transistor 20, an anode of the diode 42 is connected to an anode of the diode 44, and a cathode of the diode 44 is connected to the source S of the transistor 20.

Next, the operation of the semiconductor device 10 will be described. During normal operation of the semiconductor device 10, a positive voltage is applied to a drain D shown in FIG. 3, and the source S is grounded. When a voltage higher than the threshold voltage is applied to the gate G, the transistor 20 turns on. Since the semiconductor layer 14 is connected between the gate G and the source S in the order of the first semiconductor layer 22 of n-type, the second semiconductor layer 24 of p-type, and the third semiconductor layer 26 of n-type, no current flows through the semiconductor layer 14 when the semiconductor device 10 is at a normal operating temperature. Therefore, no short circuit occurs between the gate G and the source S of the transistor 20, and the transistor 20 can operate normally.

On the other hand, when the semiconductor device 10 operates abnormally, for example, when an abnormality such as a short circuit occurs in a load connected to the semiconductor device 10, an overcurrent flows through the transistor 20. When an overcurrent flows through the transistor 20, the temperature of the semiconductor substrate 12 rises. Then, heat is transferred from the semiconductor substrate 12 to the semiconductor layer 14 through the interlayer insulating film 16, and the temperature of the semiconductor layer 14 also rises. Accordingly, electron-hole pairs are generated in the second semiconductor layer 24, and the resistance of the second semiconductor layer 24 decreases. As a result, a current flows from the gate G to the source S of the transistor 20 through the semiconductor layer 14, the gate G and the source S are short-circuited, and the transistor 20 is forcibly turned off. Accordingly, the temperature rise of the semiconductor substrate 12 stops, and the transistor 20 can be protected from thermal breakdown.

In the semiconductor device 10 of the present embodiment, the transistor 20 and the semiconductor layer 14 are physically separated by the interlayer insulating film 16. Therefore, during normal operation of the transistor 20, parasitic conduction of the semiconductor layer 14 can be restricted. Therefore, the semiconductor device 10 of the present embodiment can effectively protect the transistor 20 from thermal destruction while restricting impairment of the operation of the transistor 20.

In the present embodiment, the semiconductor layer 14 is disposed in the peripheral region 62. Since the semiconductor layer 14 is disposed in a region where no main current flows (that is, outside the element region 60), a large area can be secured for the element region 60. Furthermore, the semiconductor layer 14 is disposed in a range sandwiched between the element regions 60. Since the semiconductor layer 14 is disposed in the range sandwiched between the element regions 60 that generate heat when an overcurrent flows through the transistor 20, the temperature of the semiconductor layer 14 is easily increased, and a short circuit can be quickly formed between the gate G and source S of the transistor 20.

In the present embodiment, the material (polysilicon) that constitutes the semiconductor layer 14 has a smaller band gap than the material (SiC) that constitutes the semiconductor substrate 12. Therefore, it is possible to short-circuit between the gate G and the source S of the transistor 20 before the drain D and the source S of the transistor 20 are short-circuited.

In the present embodiment, the peak concentration of the n-type impurity in each of the first semiconductor layer 22 and the third semiconductor layer 26 is 1×10¹⁸ cm⁻³ or more, and the peak concentration of the p-type impurity in the second semiconductor layer 24 is 5×10¹⁷ cm⁻³ or less. Therefore, the contact resistance between the first semiconductor layer 22 and the gate G and between the third semiconductor layer 26 and the source S can be reduced. Furthermore, the resistance of the second semiconductor layer 24 is quickly reduced when the temperature of the second semiconductor layer 24 increases.

### Second Embodiment

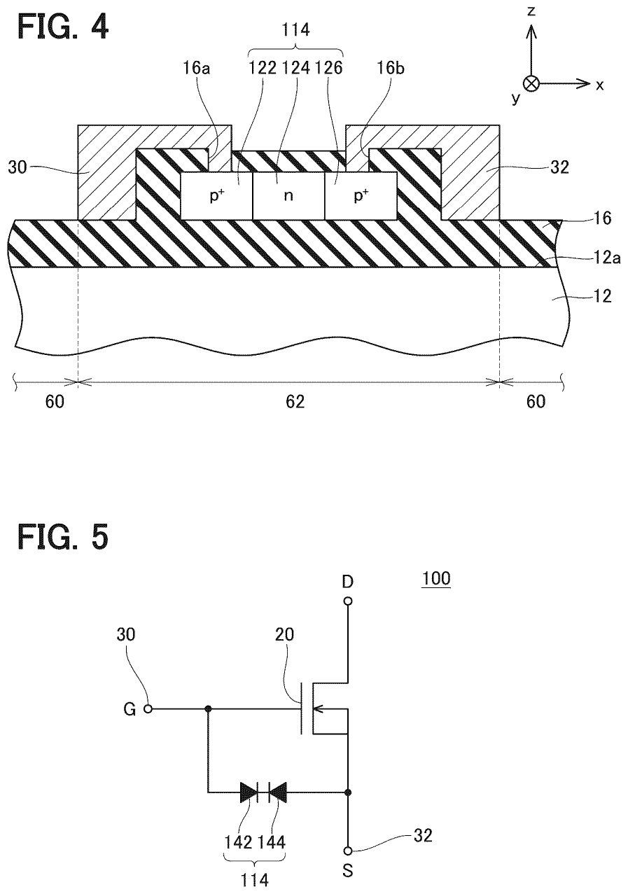

In a second embodiment, as shown in FIG. 4, a configuration of a semiconductor layer 114 is different from the configuration of the semiconductor layer 14 in the first embodiment. The semiconductor layer 114 of the second embodiment includes a first semiconductor layer 122, a second semiconductor layer 124, and a third semiconductor layer 126.

The first semiconductor layer 122 is of p-type. The first semiconductor layer 122 is connected to the gate electrode 30 via the contact hole 16a provided in the interlayer insulating film 16. The gate electrode 30 faces a body region (more specifically, a body region between a source region and a drain region) disposed inside the semiconductor substrate 12 via a gate insulating film at a position not shown. A peak concentration of the p-type impurity in the first semiconductor layer 122 is 1×10¹⁸ cm⁻³ or more.

The second semiconductor layer 124 is of n-type. The second semiconductor layer 124 is connected to the first semiconductor layer 122. A peak concentration of the n-type impurity in the second semiconductor layer 124 is 5×10¹⁷ cm⁻³ or less.

The third semiconductor layer 126 is of p-type. The third semiconductor layer 126 is connected to the second semiconductor layer 124. In addition, the third semiconductor layer 126 is connected to the source electrode 32 via the contact hole 16b provided in the interlayer insulating film 16. The source electrode 32 is in ohmic contact with the source region disposed inside the semiconductor substrate 12 at a position not shown. A peak concentration of the p-type impurity in the third semiconductor layer 126 is 1×10¹⁸ cm 3 or more.

FIG. 5 shows an equivalent circuit diagram of the semiconductor device 100 according to the second embodiment. In the semiconductor device 100 of the second embodiment, as shown in FIG. 5, it can be regarded that a diode 142 that is in a forward direction from the gate G to the source S and a diode 144 that is in a reverse direction from the gate G to the source S are connected in series in this order between the gate G and the source S of the transistor 20. In other words, in the semiconductor layer 114, an anode of the diode 142 is connected to the gate G of the transistor 20, a cathode of the diode 142 is connected to a cathode of the diode 144, and an anode of the diode 144 is connected to the source S of the transistor 20.

In the second embodiment, similarly to the first embodiment, when the semiconductor device 100 operates abnormally, the resistance of the second semiconductor layer 124 decreases. As a result, the gate G and the source S are short-circuited, and the transistor 20 is forcibly turned off. Also in the second embodiment, since the semiconductor layer 114 is physically separated from the semiconductor substrate 12 by the interlayer insulating film 16, parasitic conduction of the semiconductor layer 114 can be restricted during normal operation of the transistor 20.

### Third Embodiment

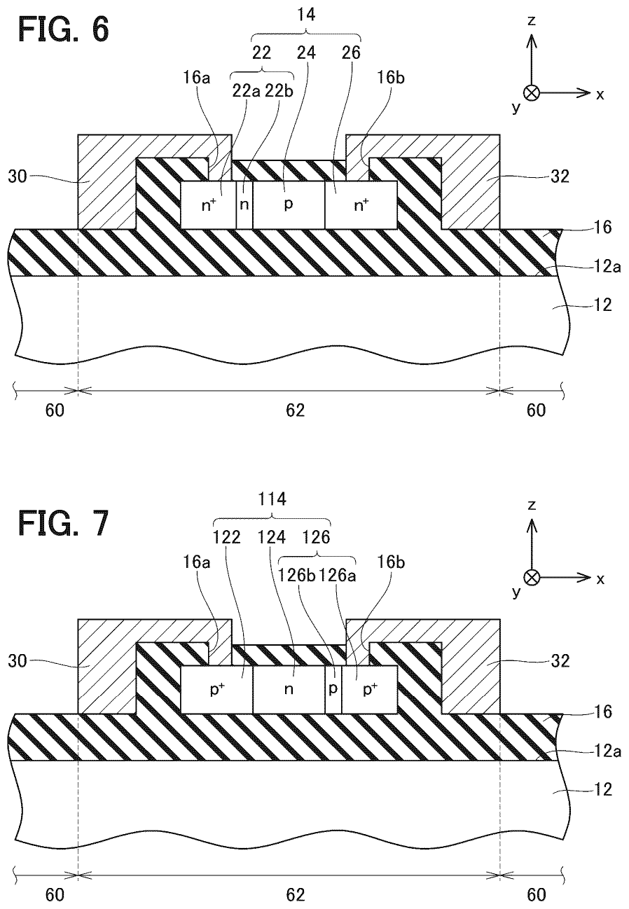

As shown in FIG. 6, a third embodiment differs from the first embodiment in that the first semiconductor layer 22 includes a high concentration region 22a and a low concentration region 22b. The other configurations of the third embodiment are similar to those of the first embodiment.

An n-type impurity concentration of the low concentration region 22b is lower than an n-type impurity concentration of the high concentration region 22a. The high concentration region 22a is disposed in a range in contact with the gate electrode 30. The low concentration region 22b is disposed in a range in contact with the second semiconductor layer 24. That is, in the third embodiment, the high concentration region 22a, the low concentration region 22b, the second semiconductor layer 24, and the third semiconductor layer 26 are connected in this order between the gate electrode 30 and the source electrode 32.

In the semiconductor device of the third embodiment, the low concentration region 22b having a relatively low n-type impurity concentration is present in the first semiconductor layer 22 located close to the gate electrode 30, so that when a positive voltage is applied to the gate electrode 30, a higher voltage can be maintained between the gate electrode 30 and the source electrode 32.

### Fourth Embodiment

As shown in FIG. 7, a fourth embodiment differs from the second embodiment in that the third semiconductor layer 126 includes a high concentration region 126a and a low concentration region 126b. The other configurations of the fourth embodiment are similar to those of the second embodiment.

A p-type impurity concentration of the low concentration region 126b is lower than a p-type impurity concentration of the high concentration region 126a. The high concentration region 126a is disposed in a range in contact with the source electrode 32. The low concentration region 126b is disposed in a range in contact with the second semiconductor layer 124. That is, in the fourth embodiment, the first semiconductor layer 122, the second semiconductor layer 124, the low concentration region 126b, and the high concentration region 126a are connected in this order between the gate electrode 30 and the source electrode 32.

In the semiconductor device of the fourth embodiment, the low concentration region 126b having a relatively low p-type impurity concentration is present in the third semiconductor layer 126 of p-type located close to the source electrode 32, so that when a positive voltage is applied to the gate electrode 30, a higher voltage can be maintained between the gate electrode 30 and the source electrode 32.

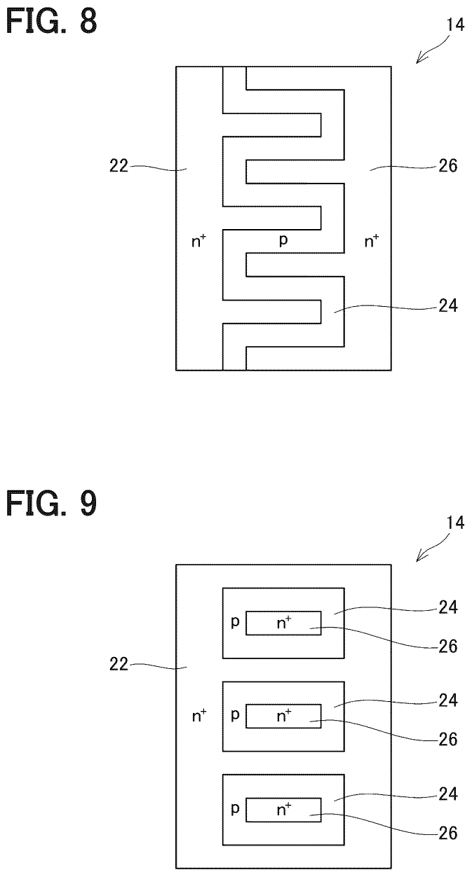

In the first embodiment described above, each of the first semiconductor layer 22, the second semiconductor layer 24, and the third semiconductor layer 26 extends linearly in the y-direction. However, for example, as shown in FIG. 8, the second semiconductor layer 24 may be configured to have a zigzag shape, and the first semiconductor layer 22 and the third semiconductor layer 26 may be disposed on either side of the second semiconductor layer 24 when the semiconductor layer 14 is viewed from above. In another example, as shown in FIG. 9, multiple second semiconductor layers 24 each having a hollow rectangular shape may be arranged, the first semiconductor layer 22 may be arranged on an outer periphery of each of the second semiconductor layers 24, and the third semiconductor layer 26 may be arranged on an inner periphery of each of the second semiconductor layer 24 when the semiconductor layer 14 is viewed from above. In these configurations, a contact area between the first semiconductor layer 22 and the second semiconductor layer 24, and a contact area between the second semiconductor layer 24 and the third semiconductor layer 26 are increased, and the resistance of the semiconductor layer 14 can be reduced. Thus, it is possible to reduce the size of the semiconductor layer 14. A similar configuration may be applied to the second to fourth embodiments.

In addition, in each of the above-described embodiments, the semiconductor layers 14 and 114 are disposed in the peripheral region 62 sandwiched between the two element regions 60 when the semiconductor substrate 12 is viewed from above. However, the semiconductor layers 14 and 114 may be disposed, for example, in the peripheral region 62 between the element region 60 and the outer circumferential edge of the semiconductor substrate 12, or may be disposed in the element region 60.

In each of the above-described embodiments, the impurity concentration of each of the semiconductor layers such as the first semiconductor layer 22, 122 is not particularly limited. The impurity concentration can be appropriately selected depending on a rated voltage of the transistor 20 and the like.

In addition, in each of the above-described embodiments, the band gap of the material constituting the semiconductor layers 14, 114 is smaller than the band gap of the material constituting the semiconductor substrate 12. However, for example, the semiconductor layers 14, 114 may be made of the same material as the semiconductor substrate 12.

In the above-described embodiments, the transistor 20 is a MOSFET. However, the transistor 20 may also be, for example, an IGBT. In this modification, the low potential terminal and the high potential terminal are the emitter and the collector, respectively.

Although the embodiments have been described in detail above, these are merely examples and do not limit the scope of claims. The techniques described in the claims include various modifications and modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve objectives at the same time, and achieving one of the objectives itself has technical usefulness.

What is claimed is:

1. A semiconductor device comprising:
a semiconductor substrate having at least one element region in which a transistor is disposed;
an interlayer insulating film disposed above the semiconductor substrate; and
a semiconductor layer disposed above the interlayer insulating film, wherein
the semiconductor layer includes:
a first semiconductor layer of a first conductivity type connected to a gate of the transistor;
a second semiconductor layer of a second conductivity type connected to the first semiconductor layer; and
a third semiconductor layer of the first conductivity type connected to the second semiconductor layer and connected to a low potential terminal of the transistor.

2. The semiconductor device according to claim 1, wherein
the semiconductor substrate further includes a peripheral region disposed around the at least one element region when the semiconductor substrate is viewed from above, and
the semiconductor layer is disposed in the peripheral region.

3. The semiconductor device according to claim 2, wherein
the at least one element region includes two element regions, and
the semiconductor layer is disposed in a range sandwiched between the two element regions when the semiconductor substrate is viewed from above.

4. The semiconductor device according to claim 1, wherein
a material that constitutes the semiconductor layer has a smaller band gap than a material that constitutes the semiconductor substrate.

5. The semiconductor device according to claim 1, wherein
a peak concentration of a first conductivity type impurity in each of the first semiconductor layer and the third semiconductor layer is 1×10¹⁸ cm⁻³ or more, and
a peak concentration of a second conductivity type impurity in the second semiconductor layer is 5×10¹⁷ cm⁻³ or less.

6. The semiconductor device according to claim 1, wherein
the first conductivity type is n-type and the second conductivity type is p-type, and
a region in the first semiconductor layer being in contact with the second semiconductor layer has a lower n-type impurity concentration than a region in the first semiconductor layer being in contact with the gate.

7. The semiconductor device according to claim 1, wherein
the first conductivity type is p-type and the second conductivity type is n-type, and
a region in the third semiconductor layer being in contact with the second semiconductor layer has a lower p-type impurity concentration than a region in the third semiconductor layer being in contact with the low potential terminal.

8. The semiconductor device according to claim 1, wherein
the semiconductor substrate is made of a wide-gap semiconductor, and
the semiconductor layer is made of polysilicon.
